(19) United States
(12) Patent Application Publication
(10) Pub. No.: US 2026/0251735 A1
(43) Pub. Date: Aug. 27, 2026

(54) MAGNET INTEGRATION FOR QUANTUM SENSOR

(71) Applicant: Mesa Quantum Systems, Inc., Boulder, CO (US)

(72) Inventors: Douglas Ray Sparks, Warren, IN (US); William Raasch, Longmont, CO (US); Sristy Agrawal, Longmont, CO (US)

(21) Appl. No.: 19/533,703

(22) Filed: Feb. 9, 2026

Related U.S. Application Data
(60) Provisional application No. 63/834,159, filed on Feb. 26, 2025.
(60) Provisional application No. 63/834,158, filed on Feb. 26, 2025.

(51) Int. Cl. G01R 33/12; G01R 33/26

(52) U.S. Cl. CPC G01R 33/1284; G01R 33/26

(57) ABSTRACT

A quantum vapor cell may include a vapor cell chamber configured to contain alkali metal vapor and a magnetic structure integrated with or positioned adjacent to the vapor cell chamber. The magnetic structure may be configured to generate, shape, or control a magnetic field through the vapor cell chamber and may include one or more of a permanent magnetic material, a soft magnetic material, a magnetic field shaping element, or a combination thereof.

### PRIORITY

This patent application claims priority from Provisional United States Patent Application number 63/834,158, filed February 26, 2025, entitled QUANTUM VAPOR CELL DESIGN AND PERMANENT MAGNET INTEGRATION and naming Douglas Ray Sparks as the inventor, and Provisional United States Patent Application number 63/834,159, filed February 26, 2025, entitled QUANTUM VAPOR CELL DESIGN AND PERMANENT MAGNET INTEGRATION and naming Douglas Ray Sparks as the inventor, the disclosure of each of which are incorporated herein in their entirety, by reference.

### FIELD

Illustrative embodiments of the invention generally relate to quantum sensing devices and, more particularly, various embodiments of the invention relate to integrated magnetic elements for quantum sensors utilizing alkali metal vapor cells.

### BACKGROUND

Vapor cells are known in the art and have been used for various applications including atomic clocks, quantum sensors, and magnetometers. These devices typically consist of a chamber with transparent windows and an alkali metal vapor. Vapor cells can be fabricated using different approaches, including MEMS (Micro-Electro-Mechanical Systems) techniques for semiconductor-based cells and glass fabrication methods for glass-type cells.

### SUMMARY OF VARIOUS EMBODIMENTS

Illustrative embodiments enable the use of standard fabrication and patterning techniques known in the field of wafer fabrication. Such methods allow for the integration of magnetic features directly into vapor cell manufacturing processes, dramatically lowering production costs and improving manufacturability of quantum sensors, including quantum magnetometers.

In accordance with one embodiment of the invention, a quantum vapor cell may include a vapor cell chamber configured to contain alkali metal vapor and a magnetic structure integrated with or positioned adjacent to the vapor cell chamber. The magnetic structure may be configured to generate, shape, or control a magnetic field through the vapor cell chamber and may include one or more of a permanent magnetic material, a soft magnetic material, a magnetic field shaping element, or a combination thereof.

In accordance with other embodiments, a magnetic structure may include a thin-film magnetic coating on interior or exterior surfaces of the vapor cell chamber.

In accordance with other embodiments, a thin-film magnetic coating may include a ferromagnetic material.

In accordance with other embodiments, a thin-film magnetic coating may have a thickness between 10 nanometers and 100 micrometers.

In accordance with other embodiments, a quantum vapor cell may include a protective coating over the magnetic coating, where the protective coating may include a material that is non-reactive with alkali metal vapor.

In accordance with other embodiments, a magnetic structure may include a magnetic wafer bonded into a wafer stack that forms the vapor cell chamber.

In accordance with other embodiments, a magnetic wafer may include a magnetic material configured to generate a magnetic field of 0.01 to 10 Gauss through the vapor cell chamber.

In accordance with other embodiments, a magnetic wafer may be positioned in a wafer stack with transparent wafers above and below to allow optical transmission through the vapor cell chamber.

In accordance with other embodiments, a magnetic structure may include one or more magnetic elements positioned external to the vapor cell chamber.

In accordance with other embodiments, one or more magnetic elements may include a high energy product magnetic material.

In accordance with other embodiments, multiple magnets may be positioned on opposite sides of the vapor cell chamber to provide a substantially uniform magnetic field through the chamber.

In accordance with other embodiments, a magnetic structure may include a soft magnetic material having a relative magnetic permeability greater than 100.

In accordance with other embodiments, a soft magnetic material may be configured to act as a flux concentrator to concentrate magnetic field lines into the vapor cell chamber.

In accordance with other embodiments, a soft magnetic material may be integrated into a wafer stack forming the vapor cell chamber.

In accordance with other embodiments, a soft magnetic material may enhance a magnetic field from a permanent magnet or one or more electromagnetic coils.

In accordance with other embodiments, a magnetic structure may include both a permanent magnetic material and a soft magnetic material, where the soft magnetic material may shape or enhance a field from the permanent magnetic material.

In accordance with other embodiments, a magnetic structure may include pole pieces configured to shape a magnetic field within the vapor cell chamber.

In accordance with other embodiments, a magnetic structure may include one or more magnetic elements positioned to surround a perimeter of the vapor cell chamber and configured to generate a magnetic field parallel to an optical axis through the vapor cell chamber.

In accordance with other embodiments, a magnetic structure may include one or more annular magnetic elements positioned substantially parallel to one or more optical windows of the vapor cell chamber.

In accordance with other embodiments, a magnetic structure may include multiple magnetic elements having different geometric configurations, the multiple magnetic elements configured to cooperate to generate a desired magnetic field profile through the vapor cell chamber.

In accordance with other embodiments, a magnetic structure may include a magnetic core with a shaped aperture positioned around the vapor cell chamber.

In accordance with other embodiments, a shaped aperture may be configured to enhance magnetic field uniformity within the vapor cell chamber.

In accordance with other embodiments, a magnetic field through the vapor cell chamber may have a strength between 0.01 and 10 Gauss.

In accordance with other embodiments, a magnetic field strength may be selected to provide Zeeman splitting of alkali atom energy levels suitable for coherent population trapping atomic clock operation.

In accordance with other embodiments, a magnetic field may be configured to tune an operating point of an atomic magnetometer.

In accordance with other embodiments, a quantum vapor cell may include a magnetic shield surrounding the vapor cell chamber, where the magnetic shield may include high-permeability material configured to attenuate external magnetic fields while allowing the magnetic structure field to persist within the shield.

In accordance with other embodiments, a magnetic shield may include a high permeability magnetic alloy.

In accordance with other embodiments, a quantum vapor cell may also include an electromagnetic element configured to provide one or more of adjustable magnetic field strength or direction, where the magnetic structure provides a base magnetic field.

In accordance with other embodiments, an electromagnetic element may include a coil positioned adjacent to the vapor cell chamber.

In accordance with other embodiments, a base magnetic field from the magnetic structure may be between 0.1 and 5 Gauss and the electromagnetic element may provide field adjustment of up to ±0.5 Gauss.

In accordance with other embodiments, a geometry of the vapor cell chamber may be configured to enable the magnetic structure to achieve a desired magnetic field strength within the vapor cell chamber.

In accordance with other embodiments, a quantum vapor cell may also include a magnetic shield surrounding the vapor cell chamber and spatially separated from the magnetic structure, where the magnetic shield is configured to attenuate external magnetic fields while preserving the magnetic field from the magnetic structure within the vapor cell chamber.

In accordance with other embodiments, a magnetic shield may include a high-permeability magnetic alloy.

In accordance with other embodiments, a quantum vapor cell may include a vapor cell chamber, a first magnetic element integrated within a structure forming the vapor cell chamber, and a second magnetic element positioned external to the vapor cell chamber, where the first magnetic element and the second magnetic element are configured to cooperate to provide a combined magnetic field through the vapor cell chamber.

In accordance with other embodiments, a first magnetic element may include a thin-film magnetic coating and the second magnetic element comprises a discrete permanent magnet.

In accordance with other embodiments, a first magnetic element may include a soft magnetic core and the second magnetic element may include a permanent magnet positioned to direct magnetic flux through the soft magnetic core.

In accordance with other embodiments, a combined magnetic field may have a field strength between 0.05 and 5 Gauss within the vapor cell chamber.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a quantum vapor cell based on a first magnetic structure of a vapor cell in accordance with a first embodiment of the invention.

FIG. 2 schematically shows a quantum vapor cell based on a second magnetic structure of a vapor cell in accordance with a second embodiment of the invention.

FIG. 3 schematically shows a quantum vapor cell based on a third magnetic structure of a vapor cell in accordance with a third embodiment of the invention.

FIG. 4A schematically shows a quantum vapor cell based on a fourth magnetic structure of a vapor cell in accordance with a fourth embodiment of the invention.

FIG. 4B schematically shows a quantum vapor cell based on a fifth magnetic structure of a vapor cell in accordance with a fifth embodiment of the invention.

FIG. 5 schematically shows a side view of a quantum vapor cell in accordance with embodiments of the invention.

FIG. 6 schematically shows a side view of a packaged quantum vapor cell in a TO form factor in accordance with embodiments of the invention.

FIG. 7 shows a flowchart of a quantum vapor cell operating process with magnetic features in accordance with embodiments of the invention.

### DESCRIPTION OF ILLUSTRATIVE EMBODIMENTS

In illustrative embodiments, the present application provides improved quantum vapor cells with magnetic features used in quantum sensing applications. The application describes various arrangements and structures for magnetic materials.

In various embodiments, permanent magnetic materials generate fields without external power or control circuitry. Permanent magnet materials may include rare-earth magnets, such as Neodymium-iron-boron (NdFeB), samarium-cobalt (SmCo), ferrite magnets, such as strontium ferrite, barium ferrite, or hard ferrite ceramics, ferromagnetic thin films, such as iron, nickel, cobalt, and their alloys (Fe-Co, Fe-Ni, Ni-Co), and amorphous magnetic alloys: Various compositions using these materials may be optimized for thin-film deposition.

In some embodiments, soft magnetic materials may be used for field enhancement, shaping, or concentration, including ferrite cores, permalloy and mu-metal, and soft magnetic thin films. Ferrite cores include soft ferrite materials that enhance magnetic fields from permanent magnets or external coils. Permalloy and mu-metal include high-permeability nickel-iron alloys for flux concentration or shielding. Soft magnetic thin films include low-coercivity materials that shape or redirect magnetic fields.

In some embodiments, magnetic field-shaping structures may also be used with quantum vapor cells. Magnetic field shaping structures include flux concentrators, pole pieces, and magnetic circuits. Flux concentrators are soft magnetic structures that concentrate field lines in the vapor cell region. Pole pieces are shaped magnetic structures that create desired specific magnetic field profiles. Magnetic circuits are combinations of permanent and soft magnetic materials optimized for field uniformity.

The choice of magnetic material or structure depends on several factors, including required magnetic field strength, temperature stability, curie temperature, fabrication compatibility, field uniformity requirements. System simplification goals, and package size constraints. Rare-earth magnets provide the strongest magnetic fields and soft magnetic materials enhance magnetic fields from other sources. Relative to temperature stability, magnetic properties should not vary significantly over the operating temperature range (typically 0°C to 70°C). The curie temperature must be above any processing temperatures (e.g., wafer bonding at 400-425°C) for permanent magnets. Fabrication must be compatible with wafer-level processing. Relative to field uniformity requirements, some applications require very uniform fields. Soft magnetic structures can shape field profiles to meet field uniformity requirements. Permanent magnets eliminate driver circuitry requirements and soft magnetic cores can reduce coil size or enhance field efficiency when coils are required. Integrated magnetic structures can reduce overall package volume compared to external coil assemblies.

While the application primarily describes improved quantum vapor cells in the context of rubidium (Rb)-based atomic clocks using Coherent Population Trapping (CPT) at 795 nm, those skilled in the art will recognize that the principles apply equally to other alkali metals (cesium, potassium, sodium), other optical transitions (including rubidium at 780 nm and cesium at 894 nm), other quantum sensing modalities (magnetometry, gyroscopes, accelerometers), and other wavelengths.

Chip-scale atomic clocks (CSACs) represent a significant advancement in miniaturized timekeeping technology. These devices utilize the quantum properties of alkali metal atoms, typically Rb or Cesium (Cs), to achieve high frequency stability in a compact form factor. Applications include GPS-denied navigation, telecommunications synchronization, distributed sensor networks, and portable instrumentation.

Many modern CSACs employ CPT, a quantum interference effect that occurs when alkali atoms are illuminated with two phase-coherent laser frequencies. For Rb-based systems, this typically involves light near 795 nm (D1 transition) or 780 nm (D2 transition). For Cs-based systems, light near 894 nm (D1 transition) is commonly used. The two frequencies are commonly generated by directly modulating a Vertical-Cavity Surface-Emitting Laser (VCSEL) at approximately 3.4 gigahertz (GHz) for Rb-87 (half the ground-state hyperfine splitting), creating optical sidebands that are separated by approximately 6.8 GHz. When this frequency difference matches the ground-state hyperfine splitting, atoms are trapped in a coherent superposition of ground states, resulting in reduced optical absorption. Traditional vapor cell designs face several challenges:

### Thermal Management

Vapor cells must be maintained at elevated temperatures (typically 60-90°C for Rb) to achieve adequate atomic vapor density. This requires heaters and thermal isolation from surrounding electronics.

### Optical Integration

The optical path typically requires a light source (often a VCSEL), beam shaping optics, polarization control elements, the vapor cell itself, and a photodetector. Assembling these components with proper alignment is challenging and costly.

### Mechanical Robustness

Vapor cells must survive shock and vibration in field applications while maintaining optical alignment.

Conventional vapor cell designs have attempted wafer-level integration but face significant limitations:

### Manual Assembly Requirements

Electrical connections to suspended vapor cells typically require manual wire bonding or assembly of polyimide flex circuits, which is labor-intensive and reduces manufacturing yield.

### Wafer Compatibility Issues

Attempts to create fully monolithic wafer stacks combining III-V semiconductor VCSELs (typically GaAs-based), MEMS vapor cells (typically silicon-based), and CMOS photodetectors face fundamental challenges including different wafer sizes, different die sizes, incompatible processing temperatures, and poor manufacturing yield (particularly for 795 nm VCSELs, which often exhibit yields below 15%).

### System Complexity

Because of these complexities and challenges, there remains a need for vapor cell designs that leverage wafer-scale fabrication for the vapor cell structure while accommodating discrete assembly of light sources and detectors with integrated magnetic structures.

Chip-scale atomic clocks and quantum sensors require precise magnetic field control for proper operation. In atomic clocks utilizing Coherent Population Trapping (CPT), a bias magnetic field is necessary to induce Zeeman splitting of atomic energy levels. This field, typically in the range of 0.05 to 0.5 Gauss, shifts atomic transition frequencies in a predictable manner and improves clock stability.

Atomic magnetometers measure external magnetic fields through their effect on atomic energy levels and present different magnetic field requirements. While magnetometers inherently respond to external fields, many configurations benefit from controlled bias fields to linearize sensor response, tune the operating point, or provide offset correction. Field uniformity is particularly important in magnetometer applications, as non-uniform fields can introduce measurement errors.

Conventional approaches to magnetic field generation in quantum vapor cells rely on electromagnetic coils positioned around the vapor cell. These coils, typically configured as solenoids or Helmholtz coil pairs, require several supporting components including driver circuitry to supply controlled current, electrical connections routed to the vapor cell region, current control loops to maintain stable field strength, and associated electronic components. This electromagnetic approach adds significant system complexity, increases component count, introduces additional potential failure modes, and requires careful thermal management to prevent interference with vapor cell temperature control.

For applications requiring static bias fields, such as CPT-based atomic clocks, electromagnetic coils represent unnecessary complexity. For applications requiring adjustable or shaped fields, such as atomic magnetometers, electromagnetic coils can benefit from field-shaping structures to improve field uniformity or enhance field efficiency. However, conventional approaches lack integrated magnetic structures that address these diverse requirements.

There remains a need for magnetic field generation and control approaches that can either eliminate electromagnetic coils and their associated driver circuitry for static field applications or enhance electromagnetic field generation through integrated field-shaping structures for applications requiring adjustable fields, while maintaining compatibility with miniaturized quantum sensor embodiments.

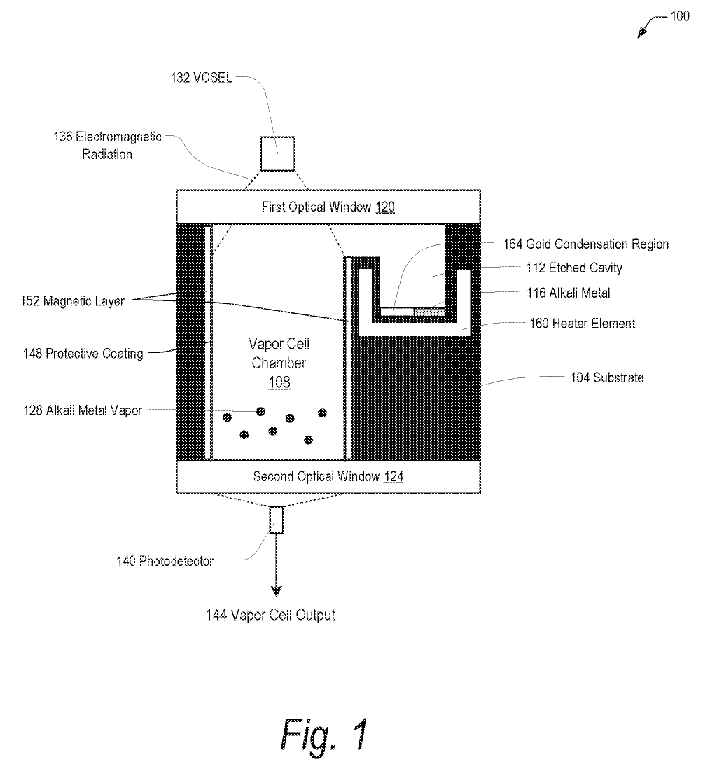

FIG. 1 schematically shows a quantum vapor cell based on a first magnetic structure 100 of a vapor cell in accordance with a first embodiment of the invention. In the first embodiment, a thin-film magnetic coating is applied to interior surfaces of a vapor cell chamber.

The vapor cell 100 is constructed with a semiconductor substrate 104, such as a silicon substrate. A vertical channel through the substrate 104 provides a vapor cell chamber 108, where electromagnetic radiation 136 or light energy interacts with alkali metal atoms, such as rubidium (Rb) or cesium (Cs) atoms within an alkali metal vapor 128.

An etched cavity 112 provides an accessible location that stores an alkali metal 116 (e.g., Rb or Cs) and a gold condensation region 164. The alkali metal 116 and gold condensation region 164 may be added to the etched cavity 112 by a metal deposition or other process. Gold regions 164 may be included as preferential condensation sites for excess alkali metal 116, thereby minimizing condensation on optical windows 120, 124.

The alkali metal 116 may be contained in a carrier material or precursor that requires activation to release the alkali metal 116. Activation methods may include laser heating, thermal activation, or other techniques depending on the alkali metal source material used. In one embodiment, the alkali metal 116 may be released in atomic form as alkali metal vapor 128 to fill the vapor cell chamber 108 by a heating process. In one embodiment, the substrate 104 may include a heater element 160. In another embodiment, a laser outside the vapor cell 100 may heat the alkali metal 116 through the first optical window 120 to release the alkali metal vapor 128 to the vapor cell chamber 108.

In one embodiment, interior or exterior side surfaces of the vapor cell chamber 108 may include a magnetic layer 152 to provide a fixed magnetic field within the vapor cell chamber 108. Magnetic material may be deposited using standard thin-film deposition techniques and subsequently magnetized to provide the desired field strength. In one embodiment, interior surfaces of the magnetic layer 152 and all other interior surfaces of the first 120 and second 124 optical windows and the etched cavity 112 may include a protective coating 148. The protective coating 148 may be an optically transparent and inert layer such as gold or alumina (AL₂O₃) to prevent oxidation and reduce reactivity with alkali vapor 128 within the vapor cell chamber 108. Alumina coatings are commonly used in alkali metal vapor cells to prevent alkali metal intrusion into substrate materials and extend cell lifetime. In this embodiment, the protective coating 148 additionally protects the magnetic layer from chemical attack by the alkali vapor 128 and may be considered as required for all other vapor cell embodiments where interior surfaces of the vapor cell chamber 108 would be directly exposed to the alkali metal vapor 128.

The vapor cell 100 may include a first optical window 120 and a second optical window 124. The first optical window 120 covers a top side of the vapor cell 100. A gap between the substrate 104 and the bottom surface of the first optical window 120 allows alkali metal vapor 128 transmission between the etched cavity 112 and the vapor cell chamber 108. The second optical window 124 covers a bottom side of the vapor cell 100. The first optical window 120 and the second optical window 124 are optically transparent to allow light from a VCSEL 132 to pass through the first optical window 120, the vapor cell chamber 108, and the second optical window 124 in sequence to reach a photodetector 140 outside the second optical window 124. The photodetector 140 converts the received light energy 136 into a vapor cell output 144. A processor or other device interprets the vapor cell output 144 to a context associated with the type of quantum sensor and application.

Various substrate 104 materials may be used, including borosilicate glass, fused silica, sapphire, silicon, and silicon-on-insulator may be used depending on optical, thermal, and mechanical requirements. Wafer bonding may be accomplished through anodic bonding, fusion bonding, frit glass bonding, eutectic bonding, or thermocompression bonding.

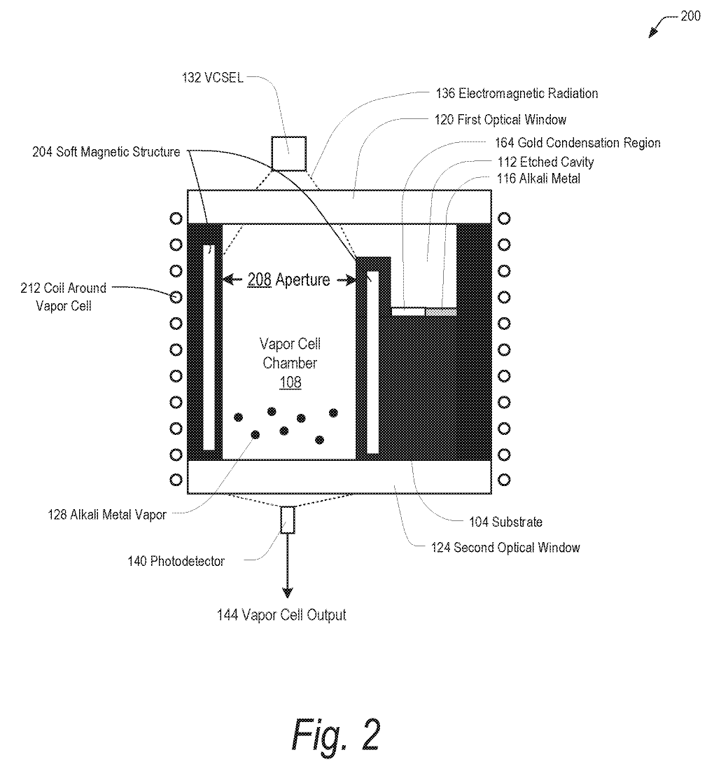

FIG. 2 schematically shows a quantum vapor cell based on a second magnetic structure 200 of a vapor cell in accordance with a second embodiment of the invention. In the second embodiment, a soft magnetic structure 204 surrounds a vapor cell chamber 108 and an electromagnetic coil is positioned around the vapor cell.

In lieu of the magnetic layer 152 applied to the inside surfaces of the vapor cell chamber 108 as shown in FIG. 1, FIG. 2 illustrates soft magnetic structures 204 embedded within the substrate 104 and surrounding the vapor cell chamber 108. The soft magnetic structure 204 acts as a flux concentrator, directing and concentrating magnetic field lines through the vapor cell chamber 108. By combining the soft magnetic material 204 with the electromagnetic coil 212

FIG. 2 includes an aperture 208, which is the diameter or width of the vapor cell chamber 108. The size of the aperture 208 affects selection of the VCSEL 132, the photodetector 140, and details of the magnetic features such as flux density. Although not specifically shown, the illustrated embodiment include the protective coating 148 shown and described with respect to FIG. 1.

In one embodiment, a wire coil may be formed around the vapor cell 212 to provide a supplemental or increased magnetic field. The wire coil 212 may be energized by a DC current to produces a uniform and unchanging magnetic field within the vapor cell chamber 108. By combining the soft magnetic material 204 with the electromagnetic coil 212, the required coil current can be dramatically reduced while achieving the desired field strength within the vapor cell chamber 108.

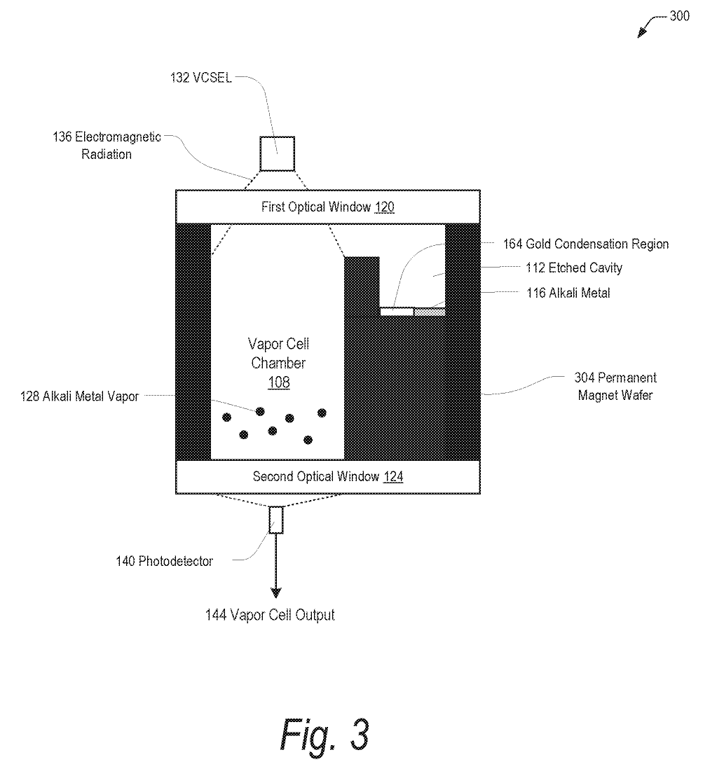

FIG. 3 schematically shows a quantum vapor cell based on a third magnetic structure 300 of a vapor cell in accordance with a third embodiment of the invention. In the third embodiment, a permanent magnetic wafer replaces or is integrated with the substrate forming the vapor cell chamber 108.

In lieu of the magnetic layer 152 applied to the inside surfaces of the vapor cell chamber 108 as shown in FIG. 1 and the magnetic structures 204 adjacent to the vapor cell chamber 108 and/or the coil provided around the outside of the vapor cell 212 of FIG. 2, FIG. 3 illustrates a permanent magnet wafer 304 integrated with or in lieu of the substrate 104. Because this permanent magnet wafer 304 would otherwise be directly exposed to the alkali metal vapor 128, the protective coating 148 would need to be applied to interior surfaces of the permanent magnet wafer 304. Although not specifically shown, the illustrated embodiment include the protective coating 148 shown and described with respect to FIG. 1.

In one embodiment, a permanent magnetic material may be incorporated as one of the wafers or layers 304 in the vapor cell stack. The magnetic wafer or layer 304 may be a bulk permanent magnet material (e.g., hard ferrite ceramic wafer), a silicon or glass wafer with a thick magnetic coating, a laminated structure with magnetic layers, or a bonded permanent magnet tile or sheet. In preferred embodiments, the vapor cell chamber 108 may be etched directly into the magnetic wafer 304, with transparent wafers 120 bonded above and below 124. Alternatively, the magnetic wafer 304 may be a separate layer in the wafer stack, positioned adjacent to a substrate layer containing the vapor cell chamber 108. In either configuration, the magnet 304 provides a magnetic field through the vapor cell region 108.

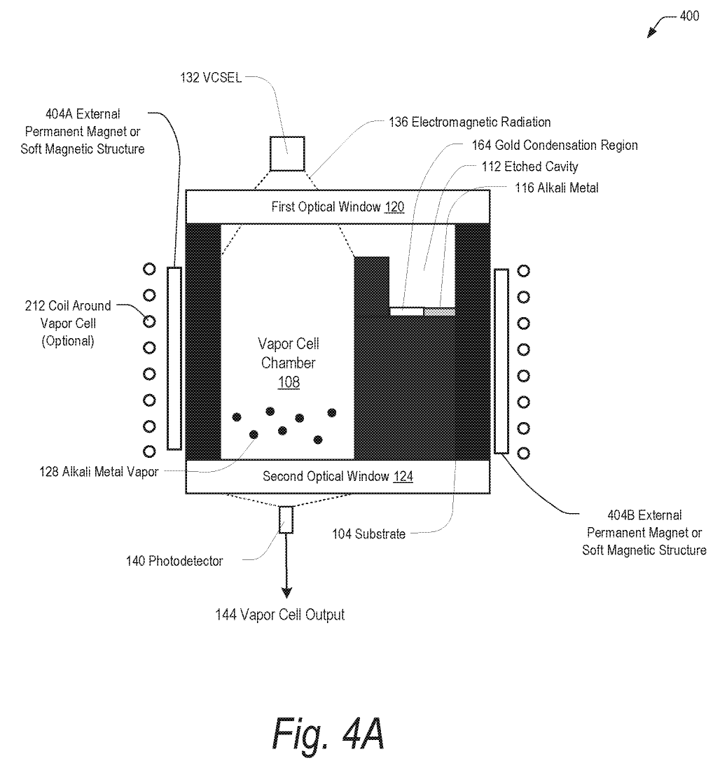

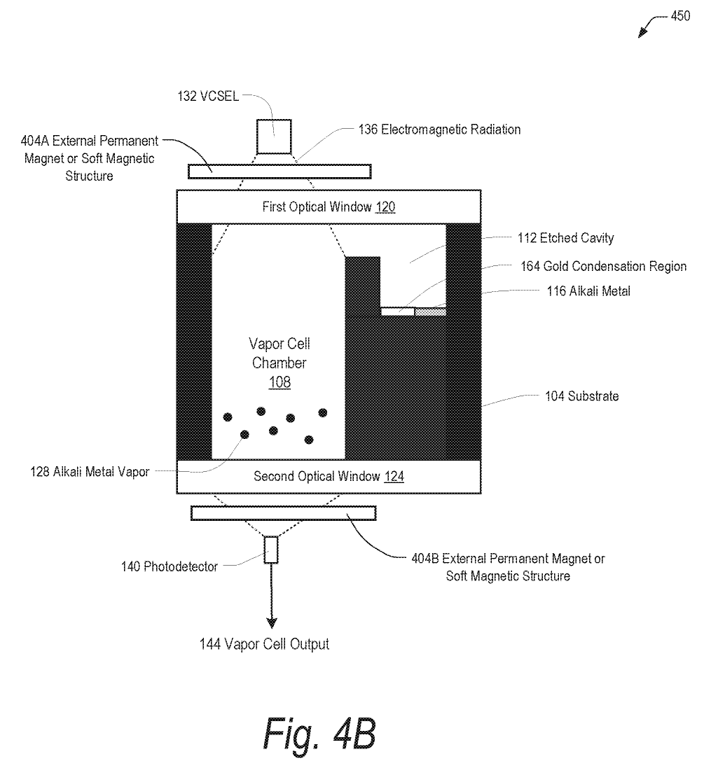

FIG. 4A schematically shows a quantum vapor cell based on a fourth magnetic structure 400 of a vapor cell in accordance with a fourth embodiment of the invention. In the fourth embodiment, magnetic structures 404A, 404B are positioned on opposite sides of the vapor chamber 108 to create a magnetic field through the vapor chamber 108 parallel to the optical axis, serving as a solenoid replacement.

In lieu of the magnetic layer 152 applied to the inside surfaces of the vapor cell chamber 108 as shown in FIG. 1, the magnetic structures 204 adjacent to the vapor cell chamber 108 and/or the coil provided around the outside of the vapor cell 212 of FIG. 2, and the permanent magnet wafer 304 integrated with or in lieu of the substrate 104 of FIG. 3, FIG. 4A illustrates external permanent or soft magnetic structures 404A, 404B that are outside of the quantum vapor cell itself. This arrangement beneficially allows a standard quantum vapor cell to be used for applications that require a magnetic field within the quantum vapor chamber 108 without modifying the quantum vapor cell chamber 108, the structure 104, or using a permanent magnet wafer 304 in lieu of the substrate 104. Although not specifically shown, the illustrated embodiment include the protective coating 148 shown and described with respect to FIG. 1.

Permanent or soft material magnets are positioned external to the vapor cell package. Large rare-earth permanent or soft magnets can be attached to the sides of the packaged vapor cell module 400, providing strong magnetic fields (1-10 Gauss or higher). In one embodiment, a wire coil 212 may be formed around the vapor cell to provide a supplemental or increased magnetic field. The wire coil 212 may be provided in lieu of or in addition to the external permanent or soft magnetic structure 404A, 404B.

In some embodiments, the external magnetic structures 404A, 404B may include multiple discrete permanent magnets positioned around the perimeter of the vapor cell chamber 108. In preferred embodiments, these multiple magnets may be arranged in a Halbach array configuration, where the magnetization direction of each magnet is rotated relative to its neighbors to concentrate magnetic flux within the chamber while minimizing external stray fields. This Halbach array configuration provides stronger, more uniform fields with less magnetic material compared to simple aligned magnets, while also reducing external stray fields that could interfere with nearby electronics or sensors. Alternatively, the external magnetic structure may comprise a continuous cylindrical or ring-shaped permanent magnet surrounding the vapor cell chamber, with magnetization oriented to create an axial field similar to a solenoid coil.

The external magnet approach offers several advantages over other arrangements, including the strongest magnetic fields achievable, magnetic structures 404A, 404B and/or the coil 212 may be added or adjusted after vapor cell fabrication, there are no constraints on magnet curie temperature, no electrical connections or driver circuitry is required for the permanent or soft magnetic structures 404A, 404B, and it allows simple integration into package design. In some embodiments. The permanent or soft external magnets 404A, 404B may be used alone or in combination with integrated magnets (thin-film or wafer-bonded) to achieve desired field strengths or gradients.

In some embodiments, multiple magnetic elements and structures may be combined. For example, integrated permanent magnets (i.e., thin-film or wafer-bonded) may provide a base field, soft magnetic cores may enhance and shape the magnetic field, external discrete permanent magnets may provide field adjustment or supplemental strength, and magnetic flux concentrators may direct the magnetic field through optimal paths.

Multiple magnetic elements allow optimization of field strength, uniformity, system complexity, and adjustability. For example, a weak integrated permanent magnet combined with a high-permeability soft magnetic core may achieve the same field as a strong permanent magnet alone, but with better field uniformity. A soft magnetic structure with external permanent or soft magnets may allow field adjustment after fabrication. Permanent magnets with soft magnetic pole pieces may create shaped field profiles. Eliminating electromagnetic coils may simplify PCB design and reduce component count.

FIG. 4B schematically shows a quantum vapor cell based on a fifth magnetic structure 450 of a vapor cell in accordance with a fifth embodiment of the invention. The fifth magnetic structure includes external magnetic structures positioned above and below a quantum vapor cell chamber 108 to create a Helmholz-like magnetic field through the vapor chamber 108.

In lieu of other embodiments using internal or side magnetic structures of FIGS. 1-4A, FIG. 4B illustrates external permanent or soft magnetic structures 404A, 404B that are outside of the quantum vapor cell itself and between the optical windows and the optical generator/receiver. External permanent magnet or soft magnetic structure 404A is positioned between the VCSEL 132 and the first optical window 120 and external permanent magnet or soft magnetic structure 404B is positioned between the photodetector 140 and the second optical window 124. Although not specifically shown, the illustrated embodiment include the protective coating 148 shown and described with respect to FIG. 1.

The geometric arrangement creates a substantially uniform magnetic field through the vapor cell chamber 108, serving as a Helmholz coil replacement. The magnetic structures 404A, 404B may be annular permanent magnets or soft magnetic structures positioned parallel to the optical structures positioned parallel to the optical windows 120, 124. The magnets are magnetized such that their field lines run vertically through the gap between them, creating a uniform axial field through the vapor cell chamber 108. By using permanent magnets in a Helmholz configuration, field uniformity is comparable to electromagnetic Helmholz coils without requiring a large coil radius and spacing requirements that typically constrain physics package dimensions.

Like the embodiment illustrated in FIG. 4A, this arrangement beneficially allows a standard quantum vapor cell to be used for applications that require a magnetic field within the quantum vapor chamber 108 without modifying the quantum vapor cell chamber 108, the structure 104, or using a permanent magnet wafer 304 in lieu of the substrate 104. The superior field uniformity of this embodiment is beneficial for certain atomic magnetometer configurations.

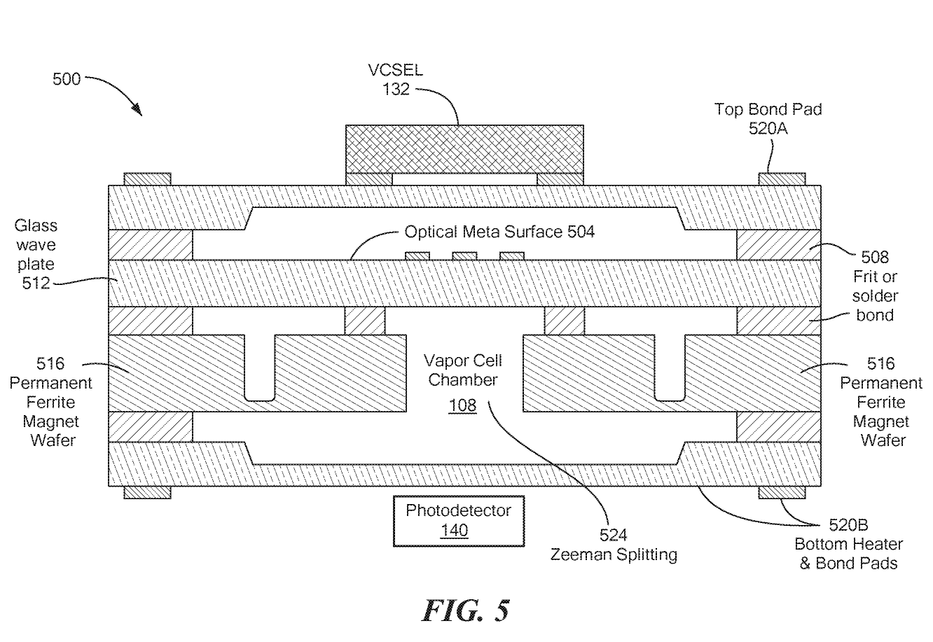

FIG. 5 schematically shows a side view of a quantum vapor cell 500 in accordance with embodiments of the invention. FIG. 5 illustrates an example of a wafer stackup for a quantum vapor cell that includes a permanent magnetic wafer integrated into a wafer stack, including optical conditioning elements and bond pads.

A VCSEL 132 is bonded to top bond pads 520A of a transparent layer providing the first optical window 120. The first optical window 120 is frit or solder bonded 508 to an optical meta surface 504 that encloses the vapor cell chamber 108 at a light source end. In one embodiment, the optical meta surface 504 may be a glass wave plate 512 such as a quarter wave plate for converting linear polarization to circular polarization.

The optical meta surface 504 may be frit or solder bonded 508 to permanent ferrite magnet wafer 516 that surrounds sides of the vapor cell chamber 108. The permanent ferrite magnet wafer 516 emits a magnetic field into the vapor cell chamber 108 to produce Zeeman splitting 524. The permanent ferrite magnet wafer 516 is coupled to the second optical window 124 by frit or solder bonds 508.

The Zeeman effect is the splitting of a spectral line into several components in the presence of a static magnetic field. It is caused by the interaction of the magnetic field with the magnetic moment of the atomic electron associated with its orbital motion and spin; this interaction shifts some orbital energies more than others, resulting in the split spectrum. A biased magnetic field is needed for Zeeman splitting of atomic energy levels in atomic clocks, or for field control and tuning in magnetometers and other quantum sensors.

Conventional approaches may use electromagnetic coils (solenoids or Helmholtz coil configurations), which require driver circuitry, electrical connections, current control loops, and associated components. Alternative approaches using permanent magnets, soft magnetic materials, or magnetic field shaping structures can eliminate these requirements while providing the necessary field control, simplifying system design and reducing component count. Although not specifically shown, the illustrated embodiment include the protective coating 148 shown and described with respect to FIG. 1.

A photodetector 140 is bonded to the external surface of the second optical window 124 and receives light projected by the VCSEL 132 and modified by the optical meta surface 504 and the permanent ferrite wafer 516. In one embodiment, a diameter of the vapor cell chamber 108 (i.e., the aperture 208) may be reduced to produce greater magnetic field interaction with the alkali metal vapor 128 and achieve an enhanced Zeeman splitting effect 524.

The present application described integrated magnetic structures into or onto the vapor cell structure to provide magnetic field generation, shaping, or control for Zeeman splitting 524 or field tuning without requiring in all embodiments electromagnetic coils and their associated driver circuitry, electrical connections, and control electronics.

In the presence of a magnetic field, atomic energy levels split due to the Zeeman effect. The specific magnetic field requirements may depend on the application:

For CPT-based atomic clocks: A bias magnetic field on the order of 0.05 to 0.5 Gauss is typically applied. This field shifts atomic transition frequencies in a predictable manner, helps discriminate between different ground-state transitions, and can improve clock stability and reduce light shift effects.

For atomic magnetometers: The device measures external magnetic fields through Zeeman splitting. Some magnetometer configurations may use small bias fields (milligauss to gauss range) to linearize sensor response or tune the operating point.

For gyroscopes and other sensors: Various configurations may use bias fields for sensor operation or tuning.

Conventional embodiments may use electromagnetic coils (solenoids or Helmholtz coil pairs) to generate these fields. They require driver electronics, current control circuits, electrical connections to the vapor cell region, and associated components that add system complexity, cost, and potential failure modes. Integrated magnetic structures eliminate these requirements, simplifying system design and improving reliability.

In some embodiments such as shown in FIGS. 4A-4B, electromagnetic coils remain advantageous where field strength adjustment or modulation is required during operation. However, for applications requiring a static bias field, integrated permanent magnets or soft magnetic structures simplify system design by eliminating coil driver requirements.

In additional embodiments, soft magnetic materials may be incorporated to enhance, shape, or concentrate magnetic fields. Soft magnetic structures offer several advantages, including field enhancement by increasing effective field strength from permanent magnets or a reduced magnet size, field shaping by creating desired field profiles (uniform fields, gradients, etc.), reduced coil requirements by dramatically reducing required current and enabling more compact designs, if electromagnets are used, and hybrid operation by combining with permanent magnets for adjustable magnetic field strength.

Soft magnetic core materials may include ferrite cores, permalloy, silicon steel, and soft magnetic thin films. Ferrite cores include soft ferrite ceramics with high permeability and low coercivity. Permalloy materials include nickel-iron alloys (e.g., 80% Ni, 20% Fe) with very high permeability. Silicon steel materials include iron-silicon alloys for lower-frequency applications. Soft magnetic thin films include deposited NiFe, CoFe, or other soft magnetic alloys.

Magnetic materials may be integrated in different ways. An integrated core wafer provides a soft magnetic wafer positioned around the vapor cell to concentrate flux. Deposited films provide thin soft magnetic films on sidewalls to shape fields. Bonded core pieces provide soft magnetic tiles or structures attached to the package. Hybrid structures provide permanent magnets with soft magnetic pole pieces to shape field distribution.

Soft magnetic structures may be used alone (with external weak fields) or in combination with integrated permanent magnets to achieve optimal field strength and uniformity.

In advantageous embodiments, the soft magnetic material is patterned into specific geometries to create desired field profiles. For example, a ring-shaped soft magnetic core with a central aperture 208 as shown in FIG. 5 can be positioned around the vapor cell chamber 108 to concentrate flux from an external permanent magnet through the vapor cell region, enhancing field uniformity. The shaped aperture 208 acts as a magnetic flux guide, directing field lines preferentially through the vapor cell 500 while minimizing stray fields in surrounding regions. The geometry can be optimized using finite element magnetic modeling and fabricated using standard photolithography and etching processes compatible with wafer-level manufacturing. Various aperture 208 shapes may be employed including circular, elliptical, or polygonal geometries depending on the desired field profile and vapor cell 500 geometry.

Wafers are bonded using anodic bonding (silicon to borosilicate glass), fusion bonding (glass to glass, silicon to silicon), frit glass bonding, eutectic metal bonding, or thermocompression bonding (Au-Au, Al-Al, Cu-Cu).

During wafer stack assembly, alkali metal sources 116 are positioned within the vapor cell chamber 108 or etched cavity 112 (shown in FIGS. 1-4B) before final hermetic sealing. The wafer stack may be diced to singulate individual vapor cell modules 500 before component attachment, or light source 132 and photodetector 140 dies may be attached to the vapor cell wafer before dicing. In either approach, known-good VCSEL 132 and photodetector 140 dies are selectively placed and attached to known-good vapor cell sites.

VCSEL 132 and photodetector 140 dies are separately fabricated, tested, and attached to the vapor cell module 500 (either as singulated modules or at wafer level before dicing) using solder bump bonding, thermocompression bonding, or adhesive attachment followed by wire bonding. After die attachment, the assembled modules are mounted on a package substrate 104 (typically an FR-4 PCB with a lead frame). Electrical connections between the vapor cell module 500 and package are made through wire bonding or bump bonding to pads 520A, 520B on the module frame.

This modular assembly approach accommodates the reality that optimal fabrication processes for VCSELs 132 (III-V semiconductors on GaAs or InP), vapor cells 500 (MEMS on silicon or glass), and photodetectors 140 (CMOS on silicon) are fundamentally different and cannot practically be integrated into a single monolithic wafer stack.

In some embodiments, electrical interconnections between the vapor cell module 500 and attached dies 132, 140 may be formed using additive manufacturing techniques such as 3D printing. For example, conductive inks or pastes may be deposited using three-dimensional printing processes to form electrical traces or bond connections between bond pads 520A, 520B on the vapor cell module 500 and corresponding pads on VCSEL 132 or photodetector 140 dies. Such printed bond connections may supplement or replace conventional wire bonding.

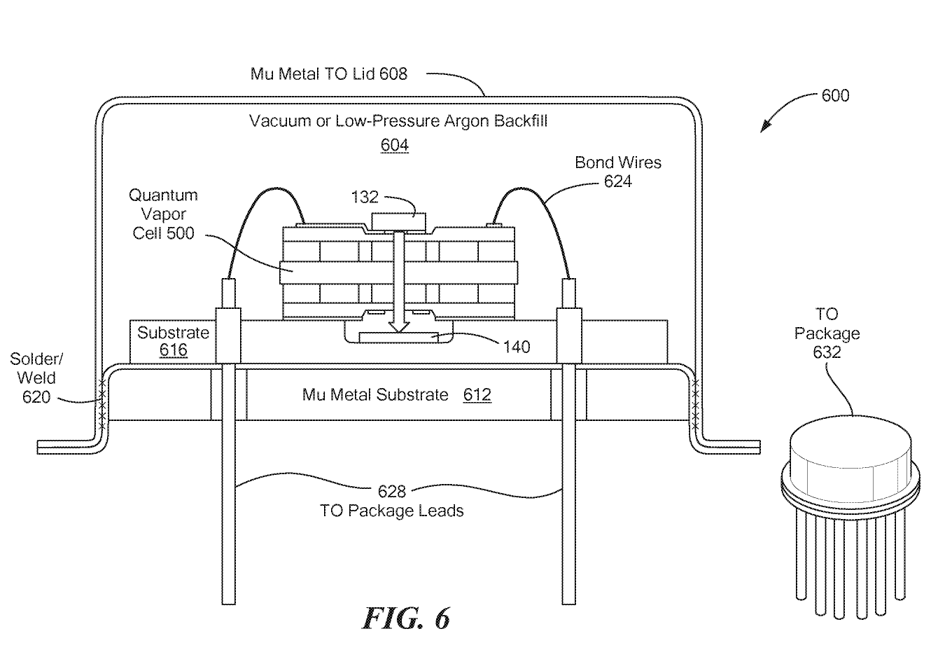

FIG. 6 schematically shows a side view of a packaged quantum vapor cell in a TO form factor 600 in accordance with embodiments of the invention. The TO package 632 may be a circular sealed package with a number of downward leads to interconnect to other circuits on a printed circuit board, a substrate, or a flexible circuit. The TO package 632 has a drum-like top portion that forms a TO package lid 608.

External magnetic fields from the environment can interfere with operation of some quantum sensors, such as atomic clocks. In preferred embodiments, the packaged vapor cell 500 may be enclosed in a magnetic shield, typically comprising high-permeability material such as mu-metal (a nickel-iron alloy) 608. The shield 608 attenuates external fields while allowing the internal permanent magnet field to persist. Shield design must account for required field strength inside the shield 608 and attenuation of external interference. The package lid 608 (and possibly the package base, as well) may be made from mu-metal or other non-magnetized substance. The TO package 632 also has a flatter bottom portion that the substrate 616 is bonded or affixed to. The TO package bottom portion is affixed to the TO package top portion 608 with solder or a weld 620.

The quantum vapor cell 500 may be bonded to a substrate 616 within the TO package 632. A number of bond wires 624 or 3D printed bond connections (not shown) may provide connections from top bond pads 520A to the package leads 628. In one embodiment, a mu-metal substrate 612 below the TO package 632 may help to isolate the magnetic field of the quantum vapor cell 500 from other fields below the TO package 632. In one embodiment, the TO package 632 may be filled with a vacuum or a low-pressure argon backfill 604 to limit interaction of moisture or other gases with the quantum vapor cell 500.

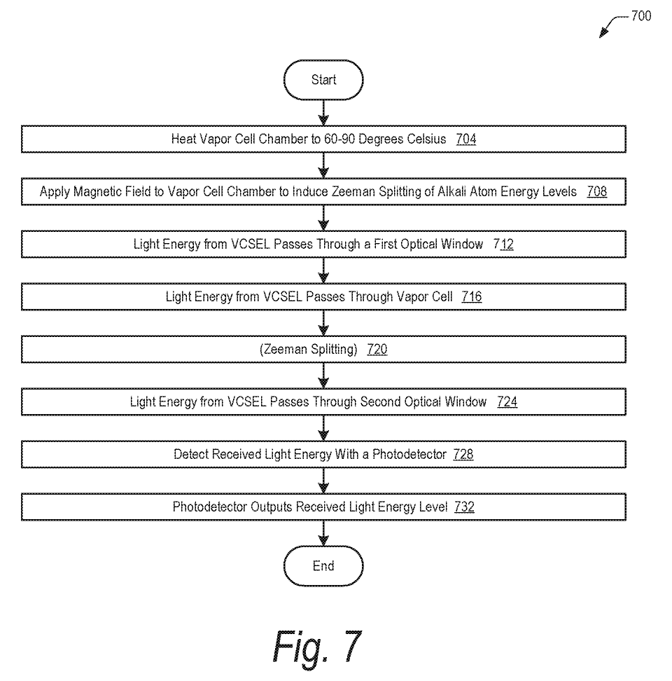

FIG. 7 shows a flowchart of a quantum vapor cell operating process with magnetic features in accordance with embodiments of the invention. FIG. 7 illustrates a process utilizing magnetic field generation for Zeeman splitting. Flow begins at block 704.

At block 704, in atomic clock embodiments, the vapor cell chamber 108 is heated to a temperature between 60 and 90 degrees Celsius to generate sufficient alkali metal vapor density. In other embodiments, a different temperature range for the vapor cell chamber 108 may be required. Flow proceeds to block 708.

At block 708, a magnetic field is applied to the vapor cell chamber 108 to induce Zeeman splitting of alkali atom energy levels. This magnetic field may be provided by any of the integrated magnetic structures described herein, including thin-film coatings, permanent magnetic wafers, external magnets, or soft magnetic structures with or without electromagnetic coils. Flow proceeds to block 712.

At block 712, light energy 136 from the VCSEL 132 passes through a first optical window 120. Flow proceeds to block 716.

At block 716, light energy 136 passes through the vapor cell chamber 108, where it interacts with the alkali metal vapor 128 in the presence of the applied magnetic field. Flow proceeds to block 720.

At block 720, Zeeman splitting occurs within the vapor cell chamber 108, due to the applied magnetic field. This splitting modifies the optical absorption properties of the alkali metal vapor 128. Flow proceeds to block 724.

At block 724, light energy 136 passes through the second optical window 124. Flow proceeds to block 728.

At block 728, a photodetector 140 receives the light energy 136 that has been modified by passage through the magnetically-influenced alkali metal vapor 128. Flow proceeds to block 732.

At block 732, the photodetector 140 outputs a signal 144 reflecting the received light energy 136 to other devices or processors to interpret and act on the light energy signal 144. This signal 144 includes information about the Zeeman splitting and can be used for atomic clock frequency references, magnetic field measurements, rotation sensing, or other quantum sensing applications. Flow ends at block 732.

Quantum vapor cells as described herein may be used for many applications, including chip-scale atomic clocks, atomic magnetometers, quantum gyroscopes, and other types of quantum sensors. For chip-scale atomic clocks, quantum vapor cells may provide stable frequency references for GPS-denied navigation, telecommunications, distributed sensors, and instrumentation. For atomic magnetometers, quantum vapor cells may measure magnetic fields with high sensitivity for geophysical exploration, biomedical imaging, defense applications, and fundamental physics research. In quantum gyroscopes, quantum vapor cells may detect rotation rates for inertial navigation systems.

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the present invention as defined in the following claims.

What is claimed is:

1. A quantum vapor cell, comprising:
a vapor cell chamber configured to contain alkali metal vapor; and
a magnetic structure integrated with or positioned adjacent to the vapor cell chamber, the magnetic structure configured to generate, shape, or control a magnetic field through the vapor cell chamber and comprising one or more of a permanent magnetic material, a soft magnetic material, a magnetic field shaping element, or a combination thereof.

2. The quantum vapor cell of claim 1, wherein the magnetic structure comprises a thin-film magnetic coating on one or more interior or exterior surfaces of the vapor cell chamber.

3. The quantum vapor cell of claim 2, wherein the thin-film magnetic coating comprises a ferromagnetic material.

4. The quantum vapor cell of claim 2, wherein the thin-film magnetic coating has a thickness between 10 nanometers and 100 micrometers.

5. The quantum vapor cell of claim 2, further comprising:
a protective coating over the magnetic coating, wherein the protective coating comprises a material that is non-reactive with alkali metal vapor.

6. The quantum vapor cell of claim 1, wherein the magnetic structure comprises a magnetic wafer bonded into a wafer stack that forms the vapor cell chamber.

7. The quantum vapor cell of claim 6, wherein the magnetic wafer comprises a magnetic material configured to generate a magnetic field of 0.01 to 10 Gauss through the vapor cell chamber.

8. The quantum vapor cell of claim 6, wherein the magnetic wafer is positioned in a wafer stack with transparent wafers above and below to allow optical transmission through the vapor cell chamber.

9. The quantum vapor cell of claim 1, wherein the magnetic structure comprises one or more magnetic elements positioned external to the vapor cell chamber.

10. The quantum vapor cell of claim 9, wherein the one or more magnetic elements comprises a high energy product magnetic material.

11. The quantum vapor cell of claim 9, wherein multiple magnets are positioned on opposite sides of the vapor cell chamber to provide a substantially uniform magnetic field through the chamber.

12. The quantum vapor cell of claim 1, wherein the magnetic structure comprises a soft magnetic material having a relative magnetic permeability greater than 100.

13. The quantum vapor cell of claim 12, wherein the soft magnetic material is configured to act as a flux concentrator to concentrate magnetic field lines into the vapor cell chamber.

14. The quantum vapor cell of claim 12, wherein the soft magnetic material is integrated into a wafer stack forming the vapor cell chamber.

15. The quantum vapor cell of claim 12, wherein the soft magnetic material enhances a magnetic field from a permanent magnet or one or more electromagnetic coils.

16. The quantum vapor cell of claim 1, wherein the magnetic structure comprises both a permanent magnetic material and a soft magnetic material, wherein the soft magnetic material shapes or enhances a field from the permanent magnetic material.

17. The quantum vapor cell of claim 1, wherein the magnetic structure comprises pole pieces configured to shape a magnetic field within the vapor cell chamber.

18. The quantum vapor cell of claim 1, wherein the magnetic structure comprises one or more magnetic elements positioned to surround a perimeter of the vapor cell chamber and configured to generate a magnetic field parallel to an optical axis through the vapor cell chamber.

19. The quantum vapor cell of claim 1, wherein the magnetic structure comprises one or more annular magnetic elements positioned substantially parallel to one or more optical windows of the vapor cell chamber.

20. The quantum vapor cell of claim 1, wherein the magnetic structure comprises multiple magnetic elements having different geometric configurations, the multiple magnetic elements configured to cooperate to generate a desired magnetic field profile through the vapor cell chamber.

21. The quantum vapor cell of claim 1, wherein the magnetic structure comprises a magnetic core with a shaped aperture positioned around the vapor cell chamber.

22. The quantum vapor cell of claim 21, wherein the shaped aperture is configured to enhance magnetic field uniformity within the vapor cell chamber.

23. The quantum vapor cell of claim 1, wherein the magnetic field through the vapor cell chamber has a strength between 0.01 and 10 Gauss.

24. The quantum vapor cell of claim 1, wherein the magnetic field strength is selected to provide Zeeman splitting of alkali atom energy levels suitable for coherent population trapping atomic clock operation.

25. The quantum vapor cell of claim 1, wherein the magnetic field is configured to tune an operating point of an atomic magnetometer.

26. The quantum vapor cell of claim 1, further comprising a magnetic shield surrounding the vapor cell chamber, wherein the magnetic shield comprises high-permeability material configured to attenuate external magnetic fields while allowing the magnetic structure field to persist within the shield.

27. The quantum vapor cell of claim 26, wherein the magnetic shield comprises a high permeability magnetic alloy.

28. The quantum vapor cell of claim 1, further comprising an electromagnetic element configured to provide one or more of adjustable magnetic field strength or direction, wherein the magnetic structure provides a base magnetic field.

29. The quantum vapor cell of claim 28, wherein the electromagnetic element comprises a coil positioned adjacent to the vapor cell chamber.

30. The quantum vapor cell of claim 28, wherein the base magnetic field from the magnetic structure is between 0.1 and 5 Gauss and the electromagnetic element provides field adjustment of up to ±0.5 Gauss.

31. The quantum vapor cell of claim 1, wherein a geometry of the vapor cell chamber is configured to enable the magnetic structure to achieve a desired magnetic field strength within the vapor cell chamber.

32. The quantum vapor cell of claim 1, further comprising:
a magnetic shield surrounding the vapor cell chamber and spatially separated from the magnetic structure, wherein the magnetic shield is configured to attenuate external magnetic fields while preserving the magnetic field from the magnetic structure within the vapor cell chamber.

33. The quantum vapor cell of claim 32, wherein the magnetic shield comprises a high-permeability magnetic alloy.

34. The quantum vapor cell of claim 32, wherein the magnetic shield comprises a plurality of permanent magnetic elements arranged in a Halbach array configuration with coordinated magnetization directions and configured to concentrate magnetic flux within the vapor cell chamber while minimizing stray magnetic fields external to the vapor cell chamber.

35. A quantum vapor cell, comprising:
a vapor cell chamber;
a first magnetic element integrated within a structure forming the vapor cell chamber; and
a second magnetic element positioned external to the vapor cell chamber,
the first magnetic element and the second magnetic element configured to cooperate to provide a combined magnetic field through the vapor cell chamber.

36. The quantum vapor cell of claim 35, wherein the first magnetic element comprises a thin-film magnetic coating and the second magnetic element comprises a discrete permanent magnet.

37. The quantum vapor cell of claim 35, wherein the first magnetic element comprises a soft magnetic core and the second magnetic element comprises a permanent magnet positioned to direct magnetic flux through the soft magnetic core.

38. The quantum vapor cell of claim 35, wherein the combined magnetic field has a field strength between 0.05 and 5 Gauss within the vapor cell chamber.
